(19) United States
(12) Patent Application Publication
(10) Pub. No.: US 2025/0007488 A1
(43) Pub. Date: Jan. 2, 2025

(54) ACOUSTIC WAVE DEVICE WITH A VARIABLE THICKNESS MULTI-LAYER PIEZOELECTRIC STRUCTURE

(71) Applicant: Skyworks Solutions, Inc., Irvine, CA (US)

(72) Inventors: Rei Goto, Osaka-Shi (JP); Yuya Hiramatsu, Neyagawa-Shi (JP)

(21) Appl. No.: 18/754,766

(22) Filed: Jun. 26, 2024

Related U.S. Application Data
(60) Provisional application No. 63/523,782, filed on Jun. 28, 2023.
(60) Provisional application No. 63/523,772, filed on Jun. 28, 2023.
(60) Provisional application No. 63/523,817, filed on Jun. 28, 2023.
(60) Provisional application No. 63/523,784, filed on Jun. 28, 2023.

(51) Int. Cl. H03H 9/02; H03H 3/08; H03H 9/25; H03H 9/64; H03H 9/72

(52) U.S. Cl. CPC H03H 9/02574; H03H 3/08; H03H 9/02559; H03H 9/02952; H03H 9/25; H03H 9/6483; H03H 9/725

(57) ABSTRACT

A surface acoustic wave device is disclosed. The surface acoustic wave device can include a support substrate structure, a first piezoelectric layer over the support substrate structure, and a second piezoelectric layer over the first piezoelectric layer. The second piezoelectric layer has a first region with a first thickness and a second region with a second thickness different from the first thickness. The surface acoustic wave device can include a first acoustic wave element that is positioned in the first region, and a second acoustic wave element that is positioned in the second region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/523,782, filed Jun. 28, 2023, titled “ACOUSTIC WAVE DEVICE HAVING PIEZOELECTRIC LAYER STRUCTURE WITH SLOPED REGION,” U.S. Provisional Patent Application No. 63/523,772, filed Jun. 28, 2023, titled “ACOUSTIC WAVE DEVICE HAVING DIFFERENT TYPES OF PIEZOELECTRIC LAYER STRUCTURES,” U.S. Provisional Patent Application No. 63/523,817, filed Jun. 28, 2023, titled “ACOUSTIC WAVE DEVICE WITH A VARIABLE THICKNESS MULTI-LAYER PIEZOELECTRIC STRUCTURE,” and U.S. Provisional Patent Application No. 63/523,784, filed Jun. 28, 2023, titled “ACOUSTIC WAVE DEVICE WITH MULTIPLE PIEZOELECTRIC LAYERS,” are hereby incorporated by reference under 37 CFR 1.57 in their entirety.

### BACKGROUND

### Technical Field

Embodiments of this disclosure relate to multilayer piezoelectric substrate (MPS) surface acoustic wave (SAW) devices.

### Description of Related Technology

A communication device such as a mobile phone, uses a filter device to separate signals having different bands, such as a transmission signal and a reception signal, for example. A surface acoustic wave (SAW) filter that includes a SAW element (e.g., SAW resonator) is an example of the filter device. The SAW resonator includes an interdigital transducer (IDT) electrode formed on a piezoelectric layer. The SAW filter can be provided as a ladder-type filter, a double mode SAW (DMS) filter, and the like.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a support substrate; a piezoelectric structure including a first region having a first thickness, a second region having a second thickness different from the first thickness, and a third region sloped between the first region and the second region; a first surface acoustic wave element positioned in the first region; and a second surface acoustic wave element positioned in the second region.

In some embodiments, the techniques described herein relate to a surface acoustic wave device wherein the piezoelectric structure further includes a fourth region having a third thickness different from the first and second thicknesses.

In some embodiments, the techniques described herein relate to a surface acoustic wave device wherein a third surface acoustic wave element is positioned in the fourth region.

In some embodiments, the techniques described herein relate to a surface acoustic wave device wherein the fourth region is positioned at a periphery of the surface acoustic wave device and the third thickness is less than the first thickness.

In some embodiments, the techniques described herein relate to a surface acoustic wave device wherein the fourth region is positioned at a periphery of the surface acoustic wave device and a surface of the support substrate facing the piezoelectric structure is partially exposed.

In some embodiments, the techniques described herein relate to a surface acoustic wave device wherein the third region is sloped between an upper surface of the first region and an upper surface of the second region.

In some embodiments, the techniques described herein relate to a surface acoustic wave device wherein the third region is sloped between a bottom surface of the first region and a bottom surface of the second region.

In some embodiments, the techniques described herein relate to a surface acoustic wave device wherein the first surface acoustic wave element is positioned on the piezoelectric structure.

In some embodiments, the techniques described herein relate to a surface acoustic wave device wherein at least a portion of the first surface acoustic wave element is positioned in the piezoelectric structure.

In some aspects, the techniques described herein relate to a surface acoustic wave device including: a support substrate; a piezoelectric structure including a first region having a first thickness, a second region having a second thickness different from the first thickness, and an acoustic obstruction structure positioned at least partially between the first region and the second region; a first surface acoustic wave element positioned in the first region; and a second surface acoustic wave element positioned in the second region.

In some embodiments, the techniques described herein relate to a surface acoustic wave device wherein the piezoelectric structure further includes a fourth region having a third thickness different from the first and second thicknesses.

In some embodiments, the techniques described herein relate to a surface acoustic wave device wherein the acoustic obstruction structure is sloped between an upper surface of the first region and an upper surface of the second region.

In some embodiments, the techniques described herein relate to a surface acoustic wave device wherein the acoustic obstruction structure is sloped between a bottom surface of the first region and a bottom surface of the second region.

In some embodiments, the techniques described herein relate to a surface acoustic wave device wherein the first surface acoustic wave element is positioned on the piezoelectric structure.

In some embodiments, the techniques described herein relate to a surface acoustic wave device wherein at least a portion of the first surface acoustic wave element is positioned in the piezoelectric structure.

In some aspects, the techniques described herein relate to a method of forming a surface acoustic wave device, the method including: providing a support substrate structure; providing a piezoelectric layer over the support substrate structure, the piezoelectric layer having a first region having a first thickness, a second region having a second thickness different from the first thickness, and a sloped region between the first region and the second region; and forming a first surface acoustic wave element in the first region and a second surface acoustic wave element in the second region.

In some embodiments, the techniques described herein relate to a method wherein providing the piezoelectric layer includes etching a portion of the piezoelectric layer to define the second region.

In some embodiments, the techniques described herein relate to a method further including removing at least an edge portion of the piezoelectric layer.

In some embodiments, the techniques described herein relate to a method wherein providing the support substrate structure includes providing a support substrate, a trap rich layer, and a functional layer.

In some embodiments, the techniques described herein relate to a method wherein the first surface acoustic wave element is formed on or at least partially in the piezoelectric layer.

In some aspects, the techniques described herein relate to a surface acoustic wave device including: a support substrate structure; a first piezoelectric layer over the support substrate structure; a second piezoelectric layer over the first piezoelectric layer; a first acoustic wave element in electrical communication with the first piezoelectric layer; and a second acoustic wave element in electrical communication with the second piezoelectric layer.

In some embodiments, the techniques described herein relate to a surface acoustic wave device wherein the second piezoelectric layer includes a sloped sidewall.

In some embodiments, the techniques described herein relate to a surface acoustic wave device wherein the first acoustic wave element includes a first interdigital transducer electrode and the second acoustic wave element includes a second interdigital transducer electrode.

In some embodiments, the techniques described herein relate to a surface acoustic wave device wherein the first acoustic wave element is a first filter and the second acoustic wave element is a second filter.

In some embodiments, the techniques described herein relate to a surface acoustic wave device wherein the first acoustic wave element is a series resonator and the second acoustic wave element is a shunt resonator.

In some embodiments, the techniques described herein relate to a surface acoustic wave device wherein at least a portion of the support substrate structure at least a portion of the second piezoelectric layer, and at least a portion of the first and second acoustic wave elements define an upper side of the surface acoustic wave device.

In some embodiments, the techniques described herein relate to a surface acoustic wave device wherein the first acoustic wave element is formed on or at least partially in the first piezoelectric layer.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein a thickness of the second piezoelectric layer is less than 500 nm.

In some embodiments, the techniques described herein relate to a surface acoustic wave device wherein a thickness of the second piezoelectric layer is less than 250 nm.

In some aspects, the techniques described herein relate to a surface acoustic wave device including: a support substrate; a piezoelectric structure including a first region having a first piezoelectric layer and a second region having the first piezoelectric layer and a second piezoelectric layer, the first region not including the second piezoelectric layer; a first surface acoustic wave element positioned in the first region; and a second surface acoustic wave element positioned in the second region.

In some embodiments, the techniques described herein relate to a surface acoustic wave device wherein the second piezoelectric layer is formed over the first piezoelectric layer and the second surface acoustic wave element is formed with the second piezoelectric layer.

In some embodiments, the techniques described herein relate to a surface acoustic wave device wherein the second piezoelectric layer includes a sloped sidewall.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein a thickness of the second piezoelectric layer is less than 500 nm.

In some embodiments, the techniques described herein relate to a surface acoustic wave device wherein a thickness of the second piezoelectric layer is less than 250 nm.

In some aspects, the techniques described herein relate to a method of forming a surface acoustic wave device, the method including: providing a support substrate; providing a first piezoelectric layer over the support substrate; providing a second piezoelectric layer over at least a portion of the first piezoelectric layer; forming a first surface acoustic wave element with the first piezoelectric layer; and forming a second surface acoustic wave element with the second piezoelectric layer.

In some embodiments, the techniques described herein relate to a method wherein providing the second piezoelectric layer includes: forming a blanket layer and etching at least a portion of the blanket layer; or forming the second piezoelectric layer by way of a lift off process.

In some aspects, the techniques described herein relate to a surface acoustic wave device including: a support substrate structure; a first piezoelectric layer over the support substrate structure; a second piezoelectric layer over the first piezoelectric layer, the second piezoelectric layer having a first region having a first thickness and a second region having a second thickness different from the first thickness; a first acoustic wave element positioned in the first region; and a second acoustic wave element positioned in the second region.

In some embodiments, the techniques described herein relate to a surface acoustic wave device wherein the support substrate structure includes a support substrate, the support substrate is a silicon layer, a quartz layer, a ceramic layer, a glass layer, a spinel layer, a magnesium oxide spinel layer, a sapphire layer, a diamond layer, a silicon carbide layer, a silicon nitride layer, or an aluminum nitride layer.

In some embodiments, the techniques described herein relate to a surface acoustic wave device wherein the support substrate structure also includes a functional layer and a trap rich layer between the support substrate and the functional layer, the functional layer is a silicon dioxide layer.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein a thickness of the second piezoelectric layer is less than 500 nm.

In some embodiments, the techniques described herein relate to a surface acoustic wave device wherein a thickness of the second piezoelectric layer is less than 250 nm.

In some embodiments, the techniques described herein relate to a surface acoustic wave device wherein the first and second acoustic wave elements are formed on or at least partially in the second piezoelectric layer.

In some embodiments, the techniques described herein relate to a surface acoustic wave device wherein the first acoustic wave element is an interdigital transducer electrode.

In some embodiments, the techniques described herein relate to a surface acoustic wave device wherein the first acoustic wave element is a first filter and the second acoustic wave element is a second filter.

In some embodiments, the techniques described herein relate to a surface acoustic wave device wherein the first acoustic wave element is a series resonator and the second acoustic wave element is a shunt resonator.

In some aspects, the techniques described herein relate to a surface acoustic wave device including: a support substrate structure; a piezoelectric structure including a first piezoelectric layer and a second piezoelectric layer over the support substrate structure, a first region of the piezoelectric structure having a first combination of thicknesses of the first and second piezoelectric layers and a second region having a second combination of thicknesses of the first and second piezoelectric layers different from the first combination; a first surface acoustic wave element positioned in the first region; and a second surface acoustic wave element positioned in the second region.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein the first acoustic wave element is a first filter and the second acoustic wave element is a second filter.

In some embodiments, the techniques described herein relate to a surface acoustic wave device wherein the first acoustic wave element is a series resonator and the second acoustic wave element is a shunt resonator.

In some aspects, the techniques described herein relate to a surface acoustic wave device including: a multilayer piezoelectric substrate including a support substrate, a first piezoelectric layer, and a second piezoelectric layer; a first surface acoustic wave element in electrical communication with the multilayer piezoelectric substrate and positioned in a first region of the multilayer piezoelectric substrate having a first combination of thicknesses of the first and second piezoelectric layers; and a second surface acoustic wave element in electrical communication with multilayer piezoelectric substrate and positioned in a second region of the multilayer piezoelectric substrate having a second combination of thicknesses of the first and second piezoelectric layers different from the first combination.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein the first acoustic wave element is a series resonator and the second acoustic wave element is a shunt resonator.

In some aspects, the techniques described herein relate to a surface acoustic wave device including: a support substrate structure; a first piezoelectric layer over the support substrate structure; a second piezoelectric layer over the first piezoelectric layer; and an interdigital transducer electrode in electrical communication with the second piezoelectric layer.

In some embodiments, the techniques described herein relate to a surface acoustic wave device further including a second interdigital transducer electrode in electrical communication with the second piezoelectric layer and laterally spaced from the first interdigital transducer electrode.

In some embodiments, the techniques described herein relate to a surface acoustic wave device wherein the support substrate structure includes a support substrate, the support substrate is a silicon layer, a quartz layer, a ceramic layer, a glass layer, a spinel layer, a magnesium oxide spinel layer, a sapphire layer, a diamond layer, a silicon carbide layer, a silicon nitride layer, or an aluminum nitride layer.

In some embodiments, the techniques described herein relate to a surface acoustic wave device wherein the support substrate structure also includes a functional layer and a trap rich layer between the support substrate and the functional layer, the functional layer is a silicon dioxide layer.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein a thickness of the second piezoelectric layer is less than 500 nm.

In some embodiments, the techniques described herein relate to a surface acoustic wave device wherein a thickness of the second piezoelectric layer is in a range between 50 nm and 250 nm.

In some embodiments, the techniques described herein relate to a surface acoustic wave device wherein the first interdigital transducer electrode is formed on or at least partially in the second piezoelectric layer.

In some embodiments, the techniques described herein relate to a surface acoustic wave device wherein a YX-cut angle of the second piezoelectric layer is in a range between 10° and 60°.

In some embodiments, the techniques described herein relate to a surface acoustic wave device including: a support substrate structure; a first piezoelectric layer over the support substrate structure; a second piezoelectric layer over the first piezoelectric layer; a first acoustic wave element formed with the second piezoelectric layer; and a second acoustic wave element formed with the second piezoelectric layer and laterally spaced from the first acoustic wave element.

In some embodiments, the techniques described herein relate to a surface acoustic wave device wherein the support substrate structure includes a support substrate, the support substrate is a silicon layer, a quartz layer, a ceramic layer, a glass layer, a spinel layer, a magnesium oxide spinel layer, a sapphire layer, a diamond layer, a silicon carbide layer, a silicon nitride layer, or an aluminum nitride layer.

In some embodiments, the techniques described herein relate to a surface acoustic wave device wherein the support substrate structure also includes a functional layer and a trap rich layer between the support substrate and the functional layer, the functional layer is a silicon dioxide layer.

In some embodiments, the techniques described herein relate to a surface acoustic wave device wherein the first piezoelectric layer is a lithium tantalate layer.

In some embodiments, the techniques described herein relate to a surface acoustic wave device wherein the second piezoelectric layer is a lithium niobate layer.

In some embodiments, the techniques described herein relate to a surface acoustic wave device wherein the first acoustic wave element is a first filter and the second acoustic wave element is a second filter.

In some embodiments, the techniques described herein relate to a surface acoustic wave device wherein the first acoustic wave element is a series resonator and the second acoustic wave element is a shunt resonator.

In some embodiments, the techniques described herein relate to a surface acoustic wave device including: a multilayer piezoelectric substrate including a support substrate, a first piezoelectric layer, and a second piezoelectric layer; a first surface acoustic wave element formed with the multilayer piezoelectric substrate; and a second surface acoustic wave element formed with multilayer piezoelectric substrate and laterally spaced from the first surface acoustic wave element.

In some embodiments, the techniques described herein relate to a surface acoustic wave device wherein the first piezoelectric layer is a lithium tantalate layer and the second piezoelectric layer is a lithium niobate layer.

In some embodiments, the techniques described herein relate to a surface acoustic wave device wherein the first surface acoustic wave element is a series resonator and the second surface acoustic wave element is a shunt resonator.

The present disclosure relates to U.S. Patent Application No. ______ [Attorney Docket SKYWRKS.1496A1], titled “ACOUSTIC WAVE DEVICE HAVING PIEZOELECTRIC LAYER STRUCTURE WITH SLOPED REGION,” U.S. Patent Application No. ______ [Attorney Docket SKYWRKS.1496A2], titled “ACOUSTIC WAVE DEVICE HAVING DIFFERENT TYPES OF PIEZOELECTRIC LAYER STRUCTURES,” and U.S. Patent Application No. ______ [Attorney Docket SKYWRKS.1496A4], titled “ACOUSTIC WAVE DEVICE WITH MULTIPLE PIEZOELECTRIC LAYERS,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a schematic top-plan view of the SAW device of FIG. 1A.

FIG. 2A is a schematic cross-sectional side view of a SAW device according to another embodiment.

FIG. 2B is a schematic top-plan view of the SAW device of FIG. 2A.

FIG. 3A is a schematic cross-sectional side view of a SAW device according to another embodiment.

FIG. 3B is a schematic top-plan view of the SAW device of FIG. 3A.

FIG. 4 is a schematic cross-sectional side vice of a SAW device according to another embodiment.

FIG. 5 is a graph showing simulated admittance results of a baseline SAW device and the SAW device of FIG. 4.

FIG. 6 is a graph showing simulated coupling factor k² results of the SAW device of FIG. 4.

FIG. 7A is a graph showing simulated coupling factor k² results of the baseline SAW device and the SAW device of FIG. 4 simulated with various YX-cut angles.

FIG. 7B is a graph showing results of simulated resonant temperature coefficient of frequency (TCF) relative to coupling factor k² of the SAW device of FIG. 4.

FIG. 7C is a graph showing results of simulated anti-resonant TCF relative to coupling factor k² of the SAW device of FIG. 4.

FIG. 7D is a graph showing simulated results of difference in TCF relative to coupling factor k² of the SAW device of FIG. 4.

FIGS. 8A to 8D show a method of manufacturing SAW devices according to an embodiment.

FIG. 9A is a schematic cross-sectional side view of the SAW device according to an embodiment.

FIG. 9B is a schematic top-plan view of the SAW device of FIG. 9A.

FIG. 10A is a schematic cross-sectional side view of a SAW device according to another embodiment.

FIG. 10B is a schematic top-plan view of the SAW device of FIG. 10A.

FIG. 11A is a schematic cross-sectional side view of a SAW device according to another embodiment.

FIG. 11B is a schematic top-plan view of the SAW device of FIG. 11A.

FIG. 12A is a schematic cross-sectional side view of a SAW device according to another embodiment.

FIG. 12B is a schematic top-plan view of the SAW device of FIG. 12A.

FIG. 13A is a graph showing a simulated coupling factor k² result of a series resonator positioned in a first region of the SAW device of FIGS. 12A and 12B.

FIG. 13B is a graph showing a simulated coupling factor k² result of a shunt resonator positioned in a second region of the SAW device of FIGS. 12A and 12B.

FIG. 13C is a graph that compares cut off frequencies of the SAW devices.

FIG. 14A is a schematic cross-sectional side view of a SAW device according to another embodiment.

FIG. 14B is a schematic top-plan view of the SAW device of FIG. 14A.

FIG. 15A is a schematic cross-sectional side view of a SAW device according to another embodiment.

FIG. 15B is a schematic cross-sectional side view of a SAW device according to another embodiment.

FIG. 16A illustrates a schematic top view of an end portion of a SAW device.

FIG. 16B illustrates a schematic cross-sectional side view of the end portion of the SAW device of FIG. 16A.

FIG. 16C shows a simulation image of acoustic wave propagation in the SAW device of FIGS. 16A and 16B.

FIG. 16D illustrates a schematic top view of an end portion of a SAW device.

FIG. 16E illustrates a schematic cross-sectional side view of the end portion of the SAW device of FIG. 16D.

FIG. 16F shows a simulation image of acoustic wave propagation in the SAW device of FIGS. 16D and 16E.

FIG. 16G illustrates a schematic top view of an end portion of a SAW device.

FIG. 16H illustrates a schematic cross-sectional side view of the end portion of the SAW device of FIG. 16G.

FIG. 16I shows a simulation image of acoustic wave propagation in the SAW device of FIGS. 16G and 16H.

FIG. 16J illustrates a schematic top view of an end portion of a SAW device.

FIG. 16K illustrates a schematic cross-sectional side view of the end portion of the SAW device 16J.

FIG. 16L shows a simulation image of acoustic wave propagation in the SAW device of FIGS. 16J and 16K.

FIG. 16M shows a simulation image of acoustic wave propagation through a SAW device.

FIG. 16N shows a graph of displacement or spatial vibration magnitude for the acoustic wave in the SAW device of FIG. 16M.

FIG. 16O shows a graph of maximum displacement or maximum spatial vibration magnitude for the SAW device of FIG. 16M versus taper angle for the edge of the piezoelectric layer and functional layer.

FIG. 17 is a schematic diagram of a radio frequency module that includes a surface acoustic wave resonator according to an embodiment.

FIG. 18 is a schematic diagram of a radio frequency module that includes filters with surface acoustic wave resonators according to an embodiment.

FIG. 19 is a schematic block diagram of a module that includes an antenna switch and duplexers that include a surface acoustic wave resonator according to an embodiment.

FIG. 20A is a schematic block diagram of a module that includes a power amplifier, a radio frequency switch, and duplexers that include a surface acoustic wave resonator according to an embodiment.

FIG. 20B is a schematic block diagram of a module that includes filters, a radio frequency switch, and a low noise amplifier according to an embodiment.

FIG. 21A is a schematic block diagram of a wireless communication device that includes a filter with a surface acoustic wave resonator in accordance with one or more embodiments.

FIG. 21B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

A multi-band surface acoustic wave (SAW) filter is an electronic device that can selectively filter or pass specific frequency bands in a signal. The multi-band SAW filter can operate at multiple frequency bands to filter and separate different signals. The SAW filter can incorporate multiple interdigital transducers (IDTs) that operate at two or more different resonant frequencies. The design and arrangement of the IDTs can at least in part determine a frequency response of the SAW filter. Multiple sets of IDTs with different spacing and electrode configurations can be used to create multiple resonant frequencies, enabling the filter to operate across multiple frequency bands. Multi-band SAW filters can be implemented in various wireless communication systems, such as mobile phones, Wi-Fi devices, and radar systems.

Filter size reduction can be important for module floor planning and cost reduction. A multi-band filter can be formed in a single die for filter size reduction. However, optimum electrical properties (e.g., coupling factor k², temperature coefficient of frequency (TCF), etc.) of acoustic wave elements can be different. In multilayer piezoelectric substrate (MPS) devices that includes a piezoelectric layer and one or more additional layers, electrical properties can be dependent at least in part on a stack configuration (e.g., thicknesses and materials of the layers of the multilayer piezoelectric substrate). Therefore, it can be challenging to form a plurality of acoustic wave elements in a single die.

Various embodiments disclosed herein relate to multilayer piezoelectric substrate (MPS) devices, such as MPS surface acoustic wave (SAW) devices, that include two or more acoustic wave elements formed in a single die. The MPS devices can be multi-band MPS devices, such as a multi-band filter. Various embodiments of the multi-band MSP devices disclosed herein enable improved electrical properties (e.g., coupling factor k², temperature coefficient of frequency (TCF), etc.). In some embodiments, a multi-band MSP device can include an MPS that has two or more piezoelectric layers or two or more regions in a piezoelectric layer. In some embodiments, a multi-band MSP device can include a first region that has a first piezoelectric layer thickness and a second region that has a second piezoelectric layer thickness different from the first piezoelectric layer thickness. The multi-band MSP device can further include a third region that has a third piezoelectric layer thickness different from the first and second piezoelectric layer thicknesses or has no piezoelectric layer.

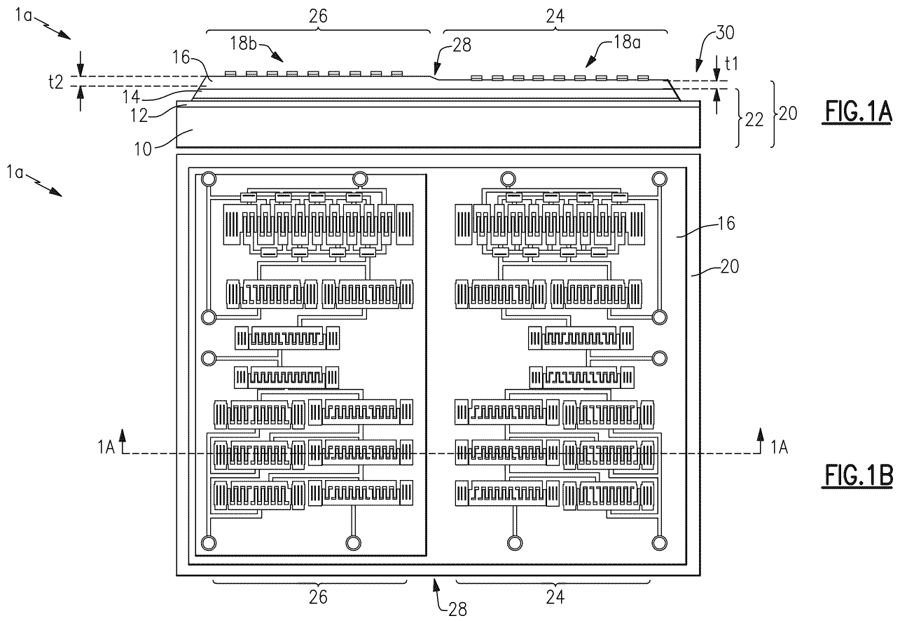

FIG. 1A is a schematic cross-sectional side view of a surface acoustic wave (SAW) device 1a according to an embodiment. FIG. 1B is a schematic top-plan view of the SAW device 1a of FIG. 1A. The SAW device 1a can include a support substrate 10, a trap rich layer 12, a functional layer 14, a piezoelectric layer 16, and interdigital transducer (IDT) electrodes that include a first acoustic wave element 18a and a second acoustic wave element 18b. The IDT electrodes can be in electrical communication with the piezoelectric layer 16. The support substrate 10, the trap rich layer 12, the functional layer 14, and the piezoelectric layer 16 can together define a multilayer piezoelectric substrate (MPS) 20, and the support substrate 10, the trap rich layer 12, and the functional layer 14 can together define a support substrate structure 22 of the MPS 20. In FIG. 1A, the number of the electrodes of the first and second acoustic wave elements are simplified/reduced for illustration purposes.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high impedance. An acoustic impedance of the support substrate 10 can be higher than an acoustic impedance of the piezoelectric layer 16. For instance, the support substrate 10 can have a higher acoustic impedance than an acoustic impedance of lithium niobate and a higher acoustic impedance than lithium tantalate.

The trap rich layer 12 can be formed at, near, on, or with the support substrate 10. In some embodiments, the trap rich layer 12 can mitigate the parasitic surface conductivity of the support substrate 10. The trap rich layer 12 can be formed in a number of ways, for example, by forming the surface of the support substrate 10 with amorphous or polycrystalline silicon, by forming the surface of the support substrate 10 with porous silicon, or by introducing defects into the surface of the support substrate 10 via ion implantation, ion milling, or other methods. In some embodiments, the trap rich layer 12 can improve the electrical characteristics of the SAW device 1a by increasing the depth and sharpness on the anti-resonance peak.

The functional layer 14 can be positioned between the trap rich layer 12 and the piezoelectric layer 16. The functional layer 14 can be a dielectric layer, such as an oxide layer (e.g., silicon oxide (SiO₂) layer, or Silicon nitride (SiN), or SiON, or a multi-layer structure of two or more of these). The functional layer 14 can enhance energy confinement and TCF tunability. In some embodiments, the functional layer 14 can be a single crystal layer arranged to confine acoustic energy and lower a higher frequency spurious response.

The piezoelectric layer 16 can be a lithium based piezoelectric layer. For example, the piezoelectric layer 16 can be a lithium niobate layer. As another example, the piezoelectric layer 16 can be a lithium tantalate layer. In certain applications, the piezoelectric layer 16 can be an aluminum nitride layer. The piezoelectric layer 16 can be any other suitable piezoelectric layer.

The piezoelectric layer 16 includes a thin region 24 (a first region) having a first thickness t1, a thick region 26 (a second region) having a second thickness t2 greater than the first thickness t1, and a sloped region 28 (a third region). The sloped region 28 can be positioned between the thin region 24 and the thick region 26 such that the sloped region 28 of the piezoelectric layer 12 extends between an upper surface of the thin region 24 and an upper surface of the thick region 26. An angle of the slope relative to the upper surface of the thin region 24 or the upper surface of the thick region 26 can be greater than zero and less than 90°. For example, the angle of the slope relative to the upper surface of the thin region 24 or the upper surface of the thick region 26 can be in a range between 15° and 89°, 15° and 75°, 25° and 75°, 35° and 75°, 25° and 65°, 35° and 75°, or 35° and 65°. The sloped region 28 can function as an acoustic obstruction structure for the second acoustic wave element 18b or between adjacent acoustic wave elements (e.g., the first acoustic wave element 18a and the second acoustic wave element 18b). For example, the sloped region 28 can reflect acoustic energy in a direction that can prevent or mitigate unwanted reflection back to the second acoustic wave element 18b.

In some embodiments, other types of acoustic obstruction structures can be implemented in addition to or in place of the sloped region 28. For example, the acoustic obstruction structures are disclosed at least in U.S. Patent Publication No. 2023/0006636, the entire contents of which are incorporated by reference herein in their entirety and for all purposes.

A thickness of the piezoelectric layer 16 relates to electrical properties (e.g., coupling factor k², temperature coefficient of frequency (TCF), etc.) of the SAW device 1a. Accordingly, the electrical properties of the first acoustic wave element 18a and the second acoustic wave element 18b can be tuned by the different thicknesses (the first and second thicknesses t1, t2) of the thin and thick regions 24, 26 of the piezoelectric layer 16. In some embodiments, the second acoustic wave element 18b that is positioned in the thick region 26 of the piezoelectric layer 16 can have a higher coupling factor k² than the first acoustic wave element 18a that is positioned in the thin region 24.

The SAW device 1a has an edge region 30. In some embodiments, the edge region 30 can be defined as a portion of the SAW device 1a within 30 μm, 25 μm, 20 μm, 15 μm, or 10 μm from a periphery of the SAW device 1a. In the edge region 30, the thickness of the piezoelectric layer 16 may be thinner than the thin region 24, or may not be present or have no thickness and a portion of the MPS 20 can be exposed on a top side of the SAW device 1a. The piezoelectric layer 16 in the edge region 30 can prevent or mitigate the piezoelectric layer 16 from being damaged (e.g., cracked) during a dicing process (e.g., a sawing process). In the edge region 30, the functional layer 14 and the trap rich layer 12 may be thinned or removed.

In some embodiments, the piezoelectric layer 16 in the edge region 30 can have a sloped profile that extends between an upper surface of the piezoelectric layer 16 (the upper surface in the thin region 24 or the upper surface in the thick region 26) to a bottom surface of the piezoelectric layer 16. The sloped profile in the edge region 30 can function as an acoustic obstruction structure.

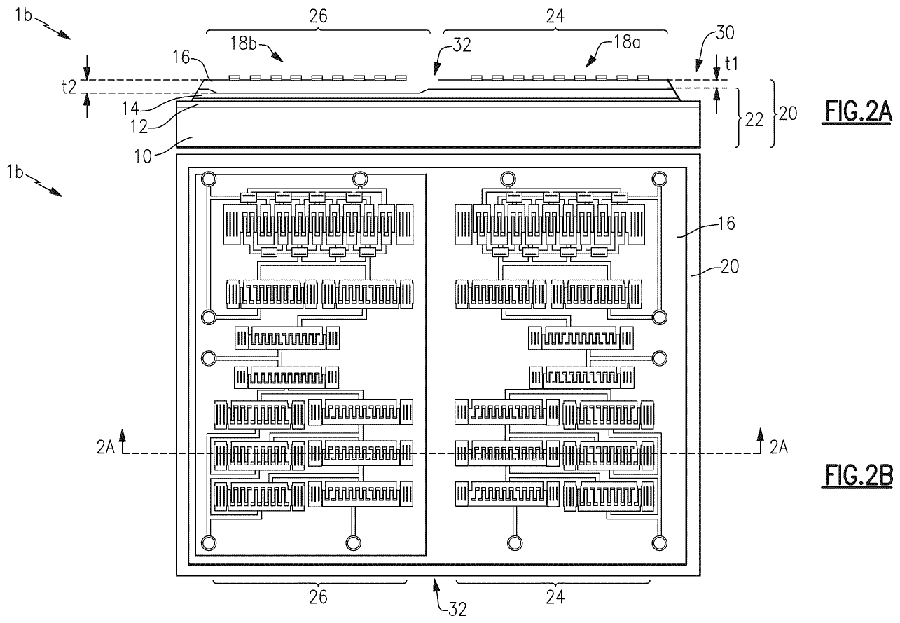

In FIGS. 1A and 1B, the upper surface of the thick region 26 is raised relative to the upper surface of the thin region 24, and the bottom surface of the piezoelectric layer 16 is flat. However, in some embodiments, the upper surface of the piezoelectric layer 16 can be flat, and the upper surfaces of the thin region 24 and the thick region 26 can be flush or coplanar with each other as shown in, for example, FIGS. 2A and 2B.

FIG. 2A is a schematic cross-sectional side view of a surface acoustic wave (SAW) device 1b according to an embodiment. FIG. 2B is a schematic top-plan view of the SAW device 1b of FIG. 2A. Unless otherwise noted, components of FIGS. 2A and 2B can be the same as or generally similar to the like components disclosed herein, such as those shown in FIGS. 1A and 1B. The SAW device 1b is generally similar to the SAW device 1a of FIGS. 1A and 1B. Unlike the SAW device 1a, the SAW device 1b has a flat upper piezoelectric layer surface and a portion of the thick region 26 of the piezoelectric layer 16 is disposed in a recess formed in the functional layer 14. Therefore, a sloped region 32 between the thin region 24 and the thick region 26 of the piezoelectric layer 16 extends between a bottom surface of the thin region 24 and a bottom surface of the thick region 26. In some embodiments, the recess in the functional layer 14 can extend completely through a thickness of the functional layer 14 such that the thick region 26 of the piezoelectric layer 16 makes direct, physical contact with the trap rich layer 12.

The difference in thicknesses (the first and second thicknesses t1, t2) of the piezoelectric layer 16 in the thin region 24 and the thick region 26 and the sloped region 32 of the SAW device 1b can provide the same or generally similar advantages and benefits as the difference in thicknesses of the piezoelectric layer 16 in the thin region 24 and the thick region 26 and the sloped region 28 of the SAW device 1a.

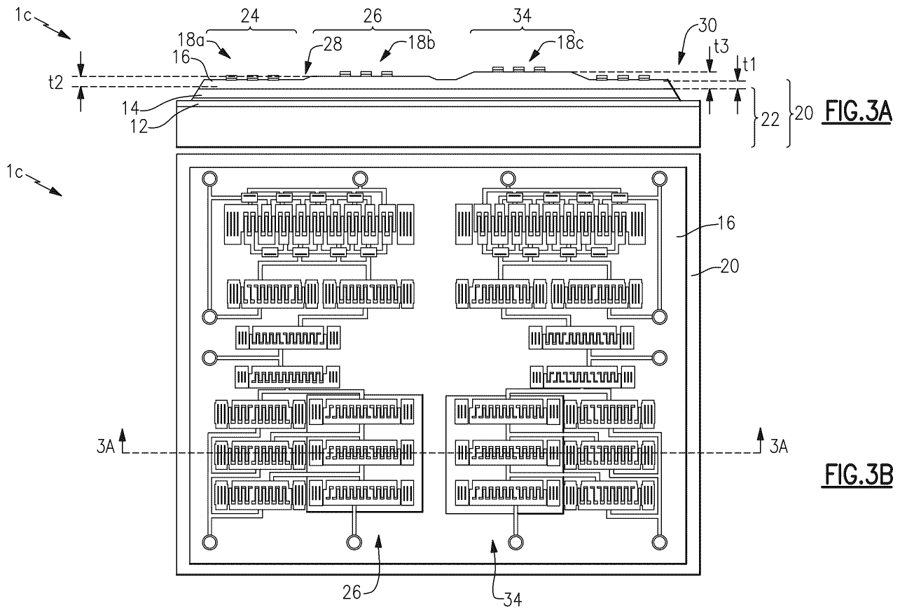

In FIGS. 1A to 2B, the first acoustic wave element 18a and the second acoustic wave element 18b each define a filter. However, in some other embodiments, the first acoustic wave element 18a and/or the second acoustic wave element 18b may define a portion of a filter or a resonator as shown in, for example, FIGS. 3A and 3B.

FIG. 3A is a schematic cross-sectional side view of a surface acoustic wave (SAW) device 1c according to an embodiment. FIG. 3B is a schematic top-plan view of the SAW device 1c of FIG. 3A. Unless otherwise noted, components of FIGS. 3A and 3B can be the same as or generally similar to the like components disclosed herein, such as those shown in FIGS. 1A to 2B.

The SAW device 1c can include a support substrate 10, a trap rich layer 12, a functional layer 14, a piezoelectric layer 16, and interdigital transducer electrodes (IDTs) that includes a first acoustic wave element 18a, a second acoustic wave element 18b, and a third acoustic wave element 18c. Unlike the SAW devices 1a and 1b of FIGS. 1A to 2B in which the first acoustic wave element 18a and the second acoustic wave element 18b each define a filter, the first to third acoustic wave elements 18a, 18b, 18c of the SAW device 1c can define portions of the filter(s). Also, the SAW device 1c can include a second thick region 34 that has a thickness t3 that is greater than the thickness t2 in the thick region 26. Each portion between adjacent regions (between the thin region 24 and the thick region 26, between the thin region 24 and the second thick region 34, and between the thick region 26 and the second thick region 34) can include a sloped region 28. For example, the sloped region 28 can extend between upper surfaces of the thin region 24 and the thick region 26, between upper surfaces of the thin region 24 and the second thick region 34, and between upper surfaces of the thick region 26 and the second thick region 34.

By adjusting the thicknesses t1, t2, t3 and the locations of the thin region 24, the thick region 26, and the second thick region 34, electrical properties of different acoustic wave elements (e.g., the first to third acoustic wave elements 18a, 18b, 18c) in the SAW device 1a, 1b, 1c can be changed or optimized. For example, by adjusting the thicknesses t1, t2, t3 and the locations of the thin region 24, the thick region 26, and the second thick region 34, the coupling factor k² can be improved or optimized. Further, by adjusting the angle of the sloped region 28, unwanted reflection of acoustic energy at a region between a thinner region and a thicker region of the piezoelectric layer can be prevented or reduced.

The interdigital transducer (IDT) electrodes that form the first acoustic wave element 18a, the second acoustic wave element 18b, and the third element 18c can have a single layer structure or a multilayer structure (e.g., dual layer, triple layer, etc.). In some embodiments, the IDT electrodes can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrodes can include two or more layers of different materials. In some embodiments, the IDT electrodes of SAW devices disclosed herein can be formed with (e.g., positioned on, over, at least partially in, or completely embedded in) a piezoelectric layer, such as the piezoelectric layer 16.

There can be a limit to the coupling factor k² of a SAW device that includes a single piezoelectric layer MPS SAW device in which only one type of piezoelectric layer is included. Various embodiments disclosed herein relate to multi-piezoelectric layer multilayer piezoelectric substrate (MPS) SAW devices that include an MPS that has two or more piezoelectric layers.

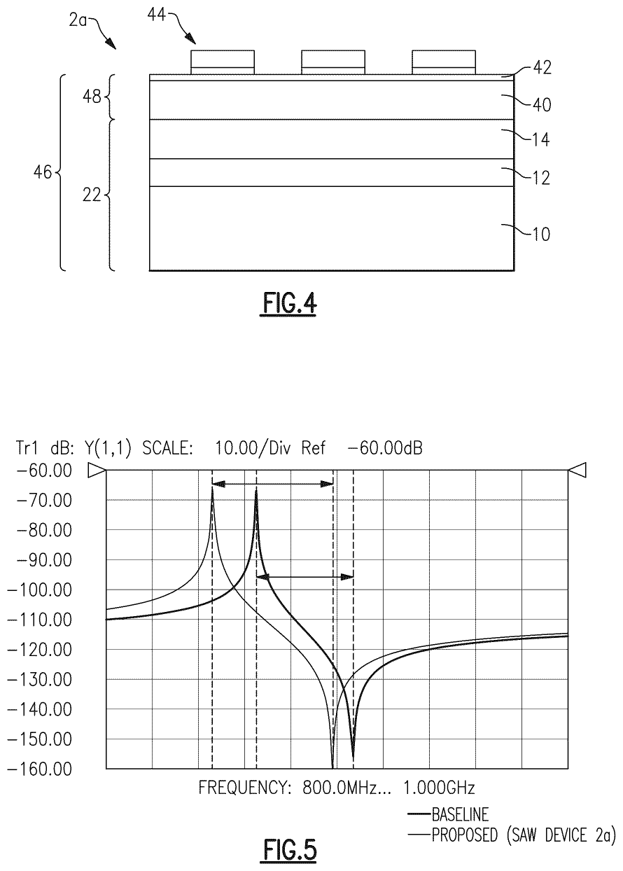

FIG. 4 is a schematic cross-sectional side view of a surface acoustic wave (SAW) device 2a according to an embodiment. Unless otherwise noted, components of FIG. 4 can be the same as or generally similar to the like components disclosed herein, such as those shown in FIGS. 1A to 3B. The SAW device 2a can include a support substrate 10, a trap rich layer 12, a functional layer 14, a first piezoelectric layer 40, a second piezoelectric layer 42, and an acoustic wave element 44, such as an interdigital transducer (IDT) electrode. The trap rich layer 12 and the functional layer 14 can be positioned between the support substrate 10 and the first piezoelectric layer 40. The second piezoelectric layer 42 can at least partially (e.g., completely) cover an upper surface of the first piezoelectric layer 40. The support substrate 10, the trap rich layer 12, the functional layer 14, the first piezoelectric layer 40, and the second piezoelectric layer 42 can define a multilayer piezoelectric substrate (MPS) 46. The support substrate 10, the trap rich layer 12, and the functional layer 14 can define a support substrate structure 22 of the MPS 46, and the first and second piezoelectric layers 40, 42 can define a piezoelectric layer structure 48 (or a multi-piezoelectric layer structure) of the MPS 46.

In some embodiments, the first and second piezoelectric layers 40, 42 can include lithium-based materials. For example, the first piezoelectric layer 40 can be a lithium tantalate (LT or LiTaO₃) layer and the second piezoelectric layer 42 can be a lithium niobate (LN or LiNbO₃). The acoustic wave element 44 can be in physical contact with the second piezoelectric layer 42.

FIG. 5 is a graph showing simulated admittance results of a baseline SAW device and the SAW device 2a of FIG. 4. The baseline SAW device is generally similar to the SAW device 2a but the baseline SAW device does not include the second piezoelectric layer 42. The baseline SAW device includes a silicon support substrate, a 1000 nm thick poly-silicon layer over the silicon support substrate, a 1000 nm thick silicon dioxide (SiO₂) layer over the poly-silicon layer, a 1000 nm thick 42YX-LT layer over the SiO₂ layer, and an interdigital transducer (IDT) electrode having a 200 nm thick molybdenum (Mo) layer and a 200 nm thick aluminum (Al) layer over the Mo layer on the 42YX-LT layer. The SAW device 2a used in the simulation includes a silicon layer as the support substrate 10, a 1000 nm thick poly-silicon layer as the trap rich layer 12, a 1000 nm thick silicon dioxide (SiO₂) layer as the functional layer 14, a 1000 nm thick 42YX-LT layer as the first piezoelectric layer 40, a 250 nm thick 42YX-LN layer as the second piezoelectric layer 42, and an interdigital transducer (IDT) electrode having a 200 nm thick molybdenum (Mo) layer and a 200 nm thick aluminum (Al) layer as the acoustic wave element 44. For both the base line SAW device and the SAW device 2a used in the simulations, the pitch (L) is set to 4 μm and the duty factor is set to 0.5.

The simulation results indicate that inclusion of the second piezoelectric layer 42 (the 42YX-LN layer) improves the coupling factor k² while maintaining basic acoustic properties (e.g., low loss, and good temperature coefficient of frequency (TCF)) of the baseline SAW device. Accordingly, the second piezoelectric layer 42 can beneficially increase the coupling factor k² without negatively affecting the loss and TCF. The coupling factor k² of the SAW device 2a can depend at least partially on, for example, the thickness of the second piezoelectric layer 42 and/or cut angles of the first and second piezoelectric layers 40, 42.

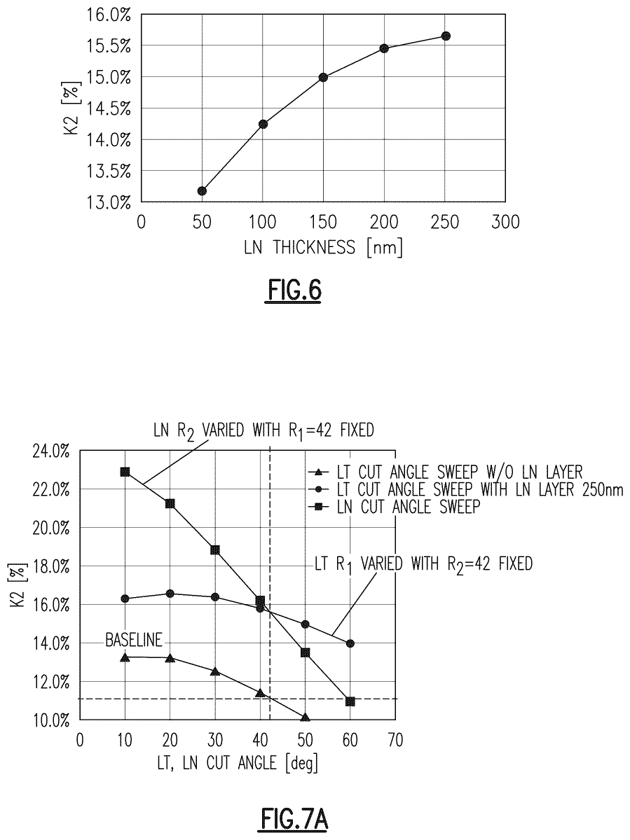

FIG. 6 is a graph showing simulated coupling factor k² results of the SAW device 2a of FIGS. 4 and 5 simulated at various thicknesses of the second piezoelectric layer 42. The simulation results of FIG. 6 indicate that the coupling factor k² of the SAW device 2a increases as the thickness of the second piezoelectric layer 42 increases. In some embodiments, the thickness of the second piezoelectric layer 42 can be in a range of 50 nm to 250 nm, 50 nm to 200 nm, 100 nm to 250 nm, 100 nm to 200 nm, or 150 nm to 250 nm.

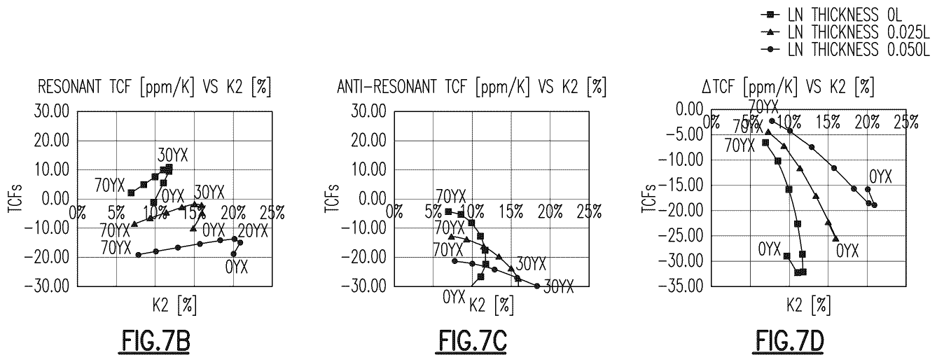

FIG. 7A is a graph showing simulated coupling factor k² results of the baseline SAW device and the SAW device 2a of FIGS. 4 and 5 simulated with various YX-cut angles of the LT layer and the first and second piezoelectric layers 40, 42. The simulation results of FIG. 7A indicate that the YX-cut angles of the LT layer and the first and second piezoelectric layers 40, 42 can impact the coupling factor k² of the baseline SAW device and the SAW device 2a. In some embodiments, the first piezoelectric layer 40 can be a lithium tantalate (LT) layer having a YX-cut angle in a range of 10° to 60°, 20° to 60°, 20° to 50°, 10° to 50°, or 30° to 50°. In some embodiments, the second piezoelectric layer 42 can be a lithium niobate (LN) layer having a YX-cut angle in a range of 10° to 60°, 20° to 60°, 20° to 50°, 10° to 50°, or 30° to 50°. In some embodiments, structural and material properties (e.g., thicknesses, cut angles, materials, etc.) of the first and second piezoelectric layers 40, 42 can be adjusted to enable the SAW device 2a to provide desired electrical properties.

FIG. 7B is a graph showing results of simulated resonant temperature coefficient of frequency (TCF) relative to coupling factor k² of the SAW device 2a of FIGS. 4 and 5 simulated with various YX-cut angles of the first and second piezoelectric layers 40, 42. FIG. 7C is a graph showing results of simulated anti-resonant temperature coefficient of frequency (TCF) relative to coupling factor k² of the SAW device 2a of FIGS. 4 and 5 simulated with various YX-cut angles of the first and second piezoelectric layers 40, 42. FIG. 7D is a graph showing simulated results of difference in resonant temperature coefficient of frequency (TCF) relative to coupling factor k² of the SAW device 2a of FIGS. 4 and 5 simulated with various YX-cut angles of the first and second piezoelectric layers 40, 42. In the simulations of FIGS. 7B-7D, the thicknesses of the functional layer and the first piezoelectric layer 40 are fixed at 0.25L, where L is a wavelength of a surface acoustic wave generated. In some embodiments, the pitch of the IDT electrodes can set the wavelength L of the surface acoustic wave.

The simulation results of FIGS. 7B-7D indicate that the resonant and anti-resonant temperature coefficient of frequencies (TCFs) and the coupling factor k² can be affected by the cut angles of the first and second piezoelectric layers 40, 42 and the thickness of the second piezoelectric layer 42. The simulation results of FIGS. 7B-7D also indicate that the second piezoelectric layer 42 enables a wider coupling factor k² tuning range for the SAW device 2a.

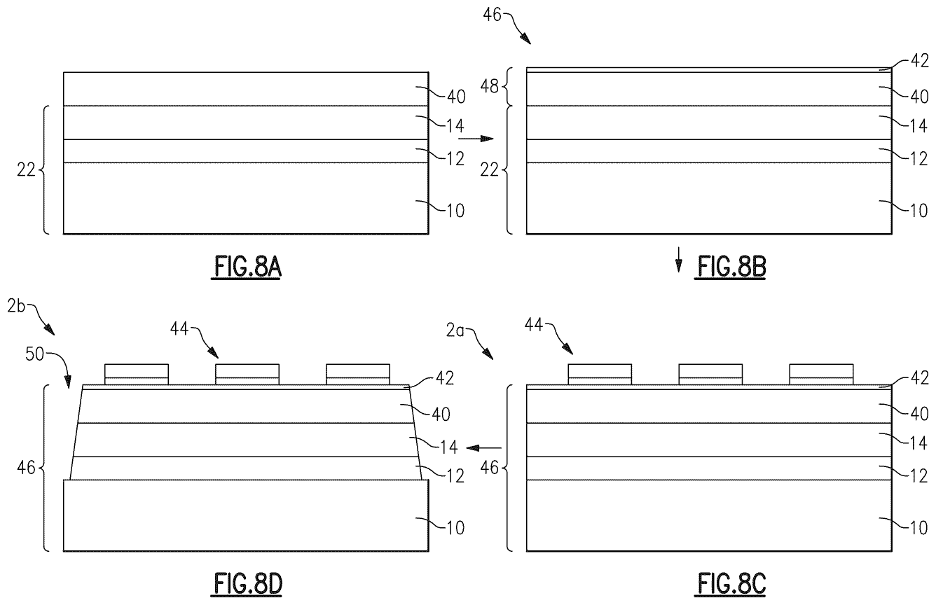

FIGS. 8A to 8D show a method of manufacturing surface acoustic wave (SAW) devices 2a, 2b according to an embodiment. The structure shown in FIGS. 8A to 8D may be a portion of a larger structure or a wafer prior to dicing. At FIG. 8A, a support substrate structure 22 that includes a support substrate 10, a trap rich layer 12, and a functional layer 14, and a first piezoelectric layer 40 over the support substrate structure 22 is provided. In some embodiments, the support substrate structure 22 and the first piezoelectric layer 40 can be bonded to one another.

At FIG. 8B, a second piezoelectric layer 42 can be formed on the first piezoelectric layer 40. In some embodiments, the second piezoelectric layer 42 can be grown or sputtered on the first piezoelectric layer 40. For example, the second piezoelectric layer 42 can be formed by way of epitaxial sputtering. The thickness of the second piezoelectric layer 42 can be less than 500 nm. For example, the thickness of the second piezoelectric layer 42 can be in a range of 50 nm, to 500 nm, 50 nm to 250 nm, 50 nm to 200 nm, 100 nm to 250 nm, 100 nm to 200 nm, or 150 nm to 250 nm.

At FIG. 8C, an acoustic wave element 44, such as an interdigital transducer (IDT) electrode can be formed. In some embodiments, the acoustic wave element 44 can be formed by way of an etching (e.g., dry etching) process or a lift off process. The structure can be diced to define the SAW device 2a.

In some embodiments, at least a portion of the MPS 46 can be removed at or near a dicing line prior to dicing to prevent or mitigate the first and second piezoelectric layers 40, 42 from being damaged (e.g., cracked). FIG. 8D shows a removed portion 50. In some embodiments, the support substrate structure 22 can be exposed through the removed portion 50. For example, an upper surface of the SAW device 2b can include at least a portion of the support substrate structure 22, at least a portion of the second piezoelectric layer 42, and at least a portion of the acoustic wave element 44.

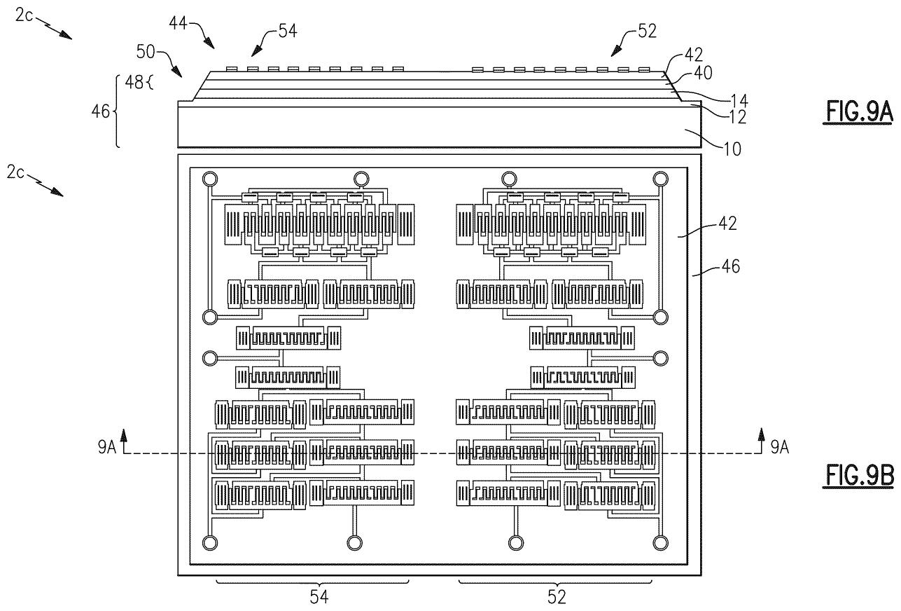

FIG. 9A is a schematic cross-sectional side view of a SAW device 2c according to an embodiment. FIG. 9B is a schematic top-plan view of the SAW device 2c of FIG. 9A. The SAW device 2c can be generally similar to the SAW device 2b of FIG. 8D. Unless otherwise noted, components of FIGS. 9A-9B can be the same as or generally similar to the like components disclosed herein, such as those shown in FIGS. 1A to 4, and FIGS. 8A-8D. As shown in FIGS. 9A and 9B, the acoustic wave element 44 can include a first acoustic wave element 52 (e.g., a first filter) and a second acoustic wave element 54 (e.g., a second filter). The first acoustic wave element 52 and the second acoustic wave element 54 can be laterally spaced from one another.

In some applications, it may be beneficial to tune electrical properties for the first acoustic wave element 52 and the second acoustic wave element 54. For example, when a SAW device is a multi-band MPS filter, and the first acoustic wave element 52 and the second acoustic wave element 54 have different bands to operate in, the first acoustic wave element 52 and the second acoustic wave element 54 may call for different electrical properties. In some embodiments, structural and material properties (e.g., thicknesses, cut angles, materials, etc.) of the first and second piezoelectric layers 40, 42 can be adjusted locally to enable a SAW device to provide desired electrical properties for different acoustic wave elements (e.g., the first acoustic wave element 52 and the second acoustic wave element 54).

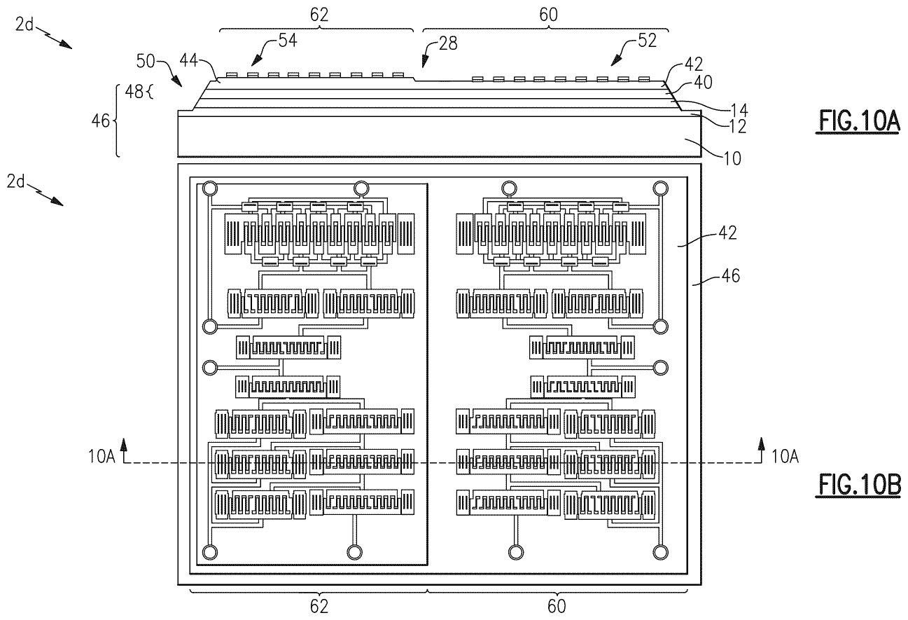

FIG. 10A is a schematic cross-sectional side view of a surface acoustic wave (SAW) device 2d according to an embodiment. FIG. 10B is a schematic top-plan view of the SAW device 2d of FIG. 10A. Unless otherwise noted, components of FIGS. 10A and 10B can be the same as or generally similar to the like components disclosed herein, such as those shown in FIGS. 1A to 4, and FIGS. 8A-9B.

The SAW device 2d can include a thin region 60 (e.g., a first region) in which the first acoustic wave element 52 is positioned, and a thick region 62 (e.g., a second region) in which the second acoustic wave element 54 is positioned. In some embodiments, the SAW device 2d can include a sloped region 64 between the thin region 60 and the thick region 62. The sloped region 64 can extend between an upper surface of the thin region 60 and an upper region of the thick region 62. The angle of the slope relative to the upper surface of the thin region 60 or the upper surface of the thick region 62 can be in a range between 15° and 89°, 15° and 75°, 25° and 75°, 35° and 75°, 25° and 65°, 35° and 75°, or 35° and 65°. The sloped region 64 can function as an acoustic obstruction structure for the second acoustic wave element 54 or between adjacent acoustic wave elements (e.g., the first acoustic wave element 52 and the second acoustic wave element 54).

A skilled artisan will understand that the thick region 62 may be formed in a recess in the functional layer 14 as with the SAW device 1b illustrated in FIGS. 2A and 2B, and that the SAW device 2d may also include more regions with different thicknesses (e.g., a second thick region) as with the SAW device 1c illustrated in FIGS. 3A and 3B. In some embodiments, the second piezoelectric layer 42 may be provided partially or locally for one or more acoustic wave elements in a SAW device.

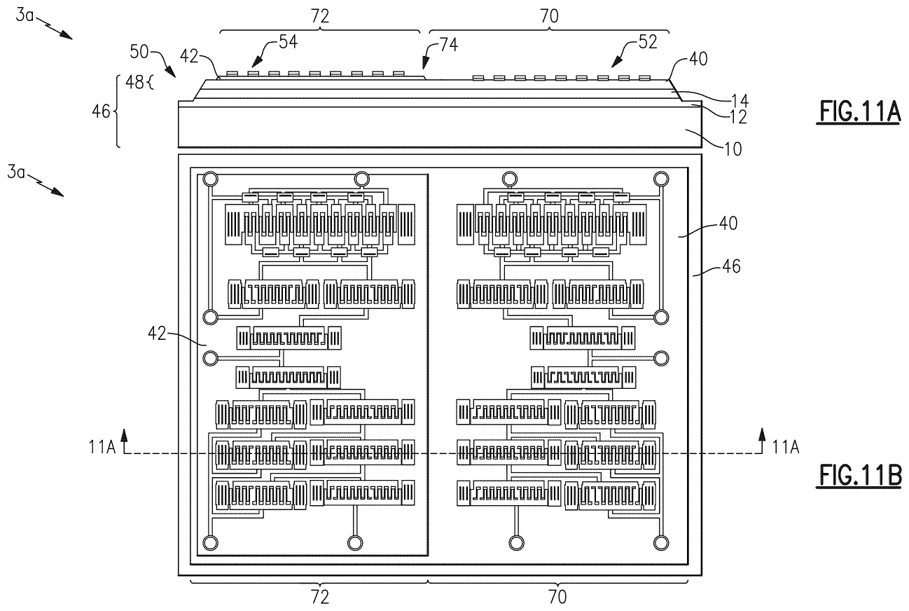

FIG. 11A is a schematic cross-sectional side view of a surface acoustic wave (SAW) device 3a according to an embodiment. FIG. 11B is a schematic top-plan view of the SAW device 3a of FIG. 11A. Unless otherwise noted, components of FIGS. 11A and 11B can be the same as or generally similar to the like components disclosed herein, such as those shown in FIGS. 1A to 4, and FIGS. 8A-10B. The SAW device 3a can be generally similar to the SAW devices 2c, 2d of FIGS. 9A-10B. Unlike the SAW devices 2c, 2d, the second piezoelectric layer 42 is locally or partially provided in the SAW device 3a. The second piezoelectric layer 42 can be formed by: first forming a blanket layer of the material of the second piezoelectric layer and etching at least a portion of the blanket layer; or forming the second piezoelectric layer 42 by way of a lift off process.

The SAW device 3a can include a support substrate 10, a trap rich layer 12, a functional layer 14, a first piezoelectric layer 40, a second piezoelectric layer 42, and first and second acoustic wave elements 52, 54, such as an interdigital transducer (IDT) electrodes. The trap rich layer 12 and the functional layer 14 can be positioned between the support substrate 10 and the first piezoelectric layer 40. The second piezoelectric layer 42 can partially cover an upper surface of the first piezoelectric layer 40. The support substrate 10, the trap rich layer 12, the functional layer 14, the first piezoelectric layer 40, and the second piezoelectric layer 42 can define a multilayer piezoelectric substrate (MPS) 46. The support substrate 10, the trap rich layer 12, the functional layer 14 can define a support substrate structure 22 of the MPS 46, and the first and second piezoelectric layers 40, 42 can define a piezoelectric layer structure 48 (or a multi-piezoelectric layer structure) of the MPS 46.

The piezoelectric layer structure 48 can include a first region 70 and a second region 72. The first region 70 can include the first piezoelectric layer 40, and the second region 72 can include the first and second piezoelectric layers 40, 42. In the illustrated embodiment, the second piezoelectric layer 42 is not provided in the first region 70. In some embodiments, the first region 70 can consists of the first piezoelectric layer 40 and no second piezoelectric layer 42 is included in the first region 70. In some embodiments, there may be more than two piezoelectric layers in the piezoelectric layer structure 48. In such embodiments, the second region 72 can include more piezoelectric layers than the first region 70.

The first acoustic wave element 52 can be positioned in the first region 70, and the second acoustic wave element 54 can be positioned in the second region 72. Various benefits and advantages disclosed herein related to the second piezoelectric layer 42 can be realized in the second region 72 thereby enabling the SAW device 3a to provide different electrical properties for the first and second acoustic wave elements 52, 54.

The SAW device 3a can include a removed portion 50 at a periphery of the SAW device 3A. The removed portion 50 can prevent or mitigate the first and second piezoelectric layers 40, 42 from being damaged (e.g., cracked). In some embodiments, the support substrate 10 can be exposed through the removed portion 50.

The SAW device 3a can include a sloped region 74 between the first region 70 and the second region 72. In some embodiments, the sloped region 74 can be a portion of the second piezoelectric layer 42. For example, the second piezoelectric layer 42 can have a sloped sidewall that defines the sloped region 74. The sloped region 74 can extend between an upper surface of the thin region 70 and an upper region of the thick region 72. The angle of the slope relative to the upper surface of the thin region 70 or the upper surface of the thick region 72 can be in a range between 15° and 89°, 15° and 75°, 25° and 75°, 35° and 75°, 25° and 65°, 35° and 75°, or 35° and 65°. The sloped region 74 can function as an acoustic obstruction structure for the second acoustic wave element 74 or between adjacent acoustic wave elements (e.g., the first acoustic wave element 52 and the second acoustic wave element 54).

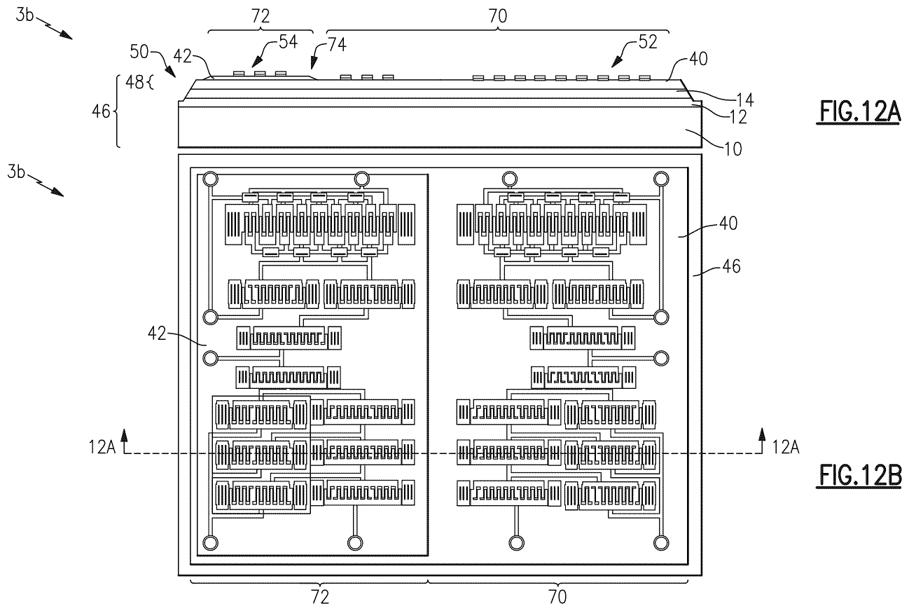

In FIGS. 10A to 11B, the first acoustic wave element 52 and the second acoustic wave element 54 each define a filter. However, in some other embodiments, the first acoustic wave element 52 and/or the second acoustic wave element 54 may define a portion of a filter or a resonator as shown in, for example, FIGS. 12A and 12B.

FIG. 12A is a schematic cross-sectional side view of a surface acoustic wave (SAW) device 3b according to an embodiment. FIG. 12B is a schematic top-plan view of the SAW device 3b of FIG. 12A. Unless otherwise noted, components of FIGS. 12A and 12B can be the same as or generally similar to the like components disclosed herein, such as those shown in FIGS. 1A to 4, and FIGS. 8A-11B. The SAW device 3b is generally similar to the SAW device 3a of FIGS. 11A and 11B. Unlike the SAW device 3a, the second acoustic wave element 54 of the SAW device 3b defines a portion of a filter. In some embodiments, as shown in FIG. 12B, the second region 72 that includes the second piezoelectric layer 42 can be defined for shunt resonators of the filter of two or more filters included in the SAW device 3b. Different portions of the filter (e.g., a series resonator) or other filters can be formed in the first region 70 that does not include the second piezoelectric layer 42.

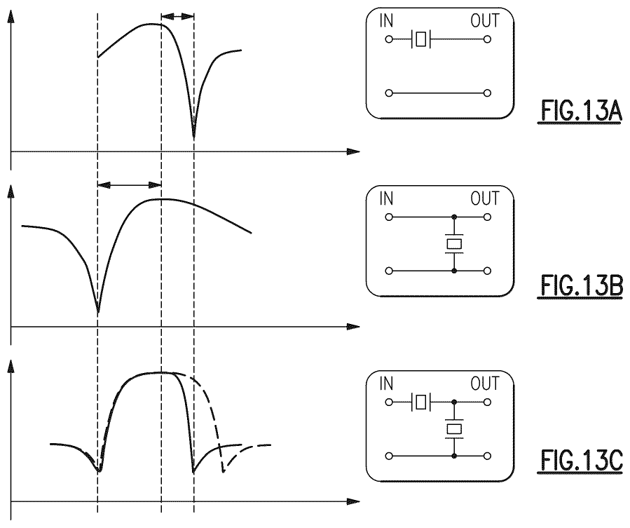

FIG. 13A is a graph showing a simulated coupling factor k² result of a series resonator positioned in the first region 70 of the SAW device 3b of FIGS. 12A and 12B. FIG. 13B is a graph showing a simulated coupling factor k² result of a shunt resonator positioned in the second region 72 of the SAW device 3b of FIGS. 12A and 12B. FIG. 13C is a graph that compares cut off frequencies of the SAW device 3b and a SAW device similar to the SAW device 3b but that does not include the second piezoelectric layer 42.

FIGS. 13A to 13C indicate that a higher coupling factor k² can be obtained for the shunt resonator that is positioned in the second region 72 of the SAW device 3b than the series resonator that is positioned in the first region 70 of the SAW device 3b. Therefore, the first region 70 may be a low k² region and the second region 72 can be a high k² region. Also, the SAW device 3b can provide a steeper cut off than the SAW device that does not include the second piezoelectric layer 42.

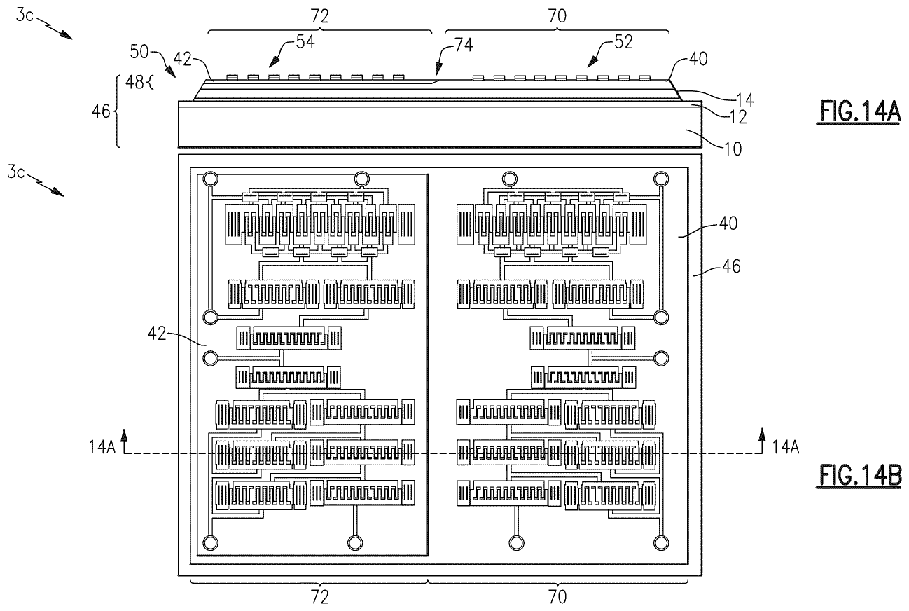

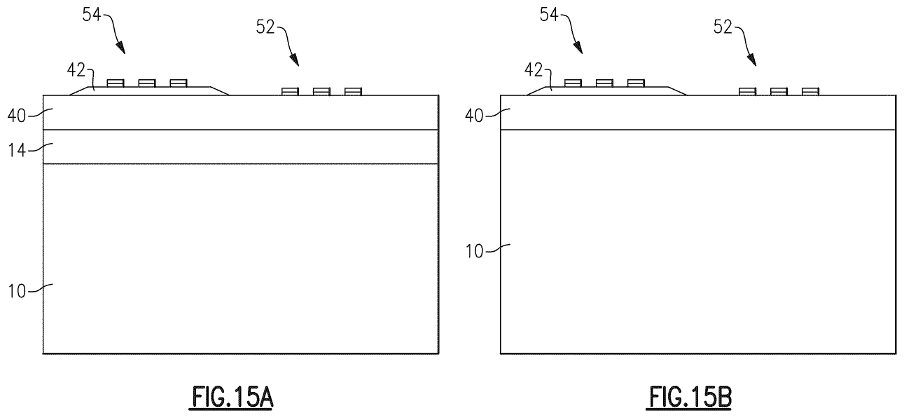

FIG. 14A is a schematic cross-sectional side view of a surface acoustic wave (SAW) device 3c according to an embodiment. FIG. 14B is a schematic top-plan view of the SAW device 3c of FIG. 14A. Unless otherwise noted, components of FIGS. 14A and 14B can be the same as or generally similar to the like components disclosed herein, such as those shown in FIGS. 1A to 4, and FIGS. 8A-12B. The SAW device 3c can be generally similar to the SAW device 3a of FIGS. 11A and 11B. Unlike the SAW device 3a, FIG. 14A shows that the first piezoelectric layer 40 can have different thicknesses in the first and second regions 70, 72. In the illustrated embodiment, the second piezoelectric layer 42 is positioned over a thinner portion of the first piezoelectric layer 40 such that an upper surface of the second piezoelectric layer 42 is flush with an upper surface of the first piezoelectric layer 40 in the first region 70. However, the upper surfaces of the second piezoelectric layer 42 and the first piezoelectric layer 40 in the first region 70 may not be flush with one another.

Structural and material properties (e.g., thicknesses, cut angles, materials, etc.) of a piezoelectric layer structure can be adjusted in any suitable manner to provide desired electrical properties for different acoustic wave elements included in a SAW device. Any suitable combinations of the features disclosed herein can be implemented in a SAW device to provide, for example, a reduced size, multi-band filter die that achieves sufficiently high coupling factor k². SAW devices in accordance with various embodiments disclosed herein can include any suitable support substrate structure (e.g., the support substrate structure 22 of the MPS 20). The support substrate structure can also affect the electrical properties of a SAW device.

FIG. 15A is a schematic cross-sectional side view of a SAW device 3d according to an embodiment. The SAW device 3d is generally similar to the SAW devices 3a and 3b of FIGS. 11A to 12B. However, the SAW device 3d does not include the trap rich layer 12 that is included in the SAW devices 3a and 3b. In such embodiments that do not include the trap rich layer 12, using sapphire, diamond-like carbon, silicon carbide, or like materials for the support substrate 10 may be preferred.

FIG. 15B is a schematic cross-sectional side view of a SAW device 3e according to an embodiment. The SAW device 3e is generally similar to the SAW device 3d of FIG. 15A. However, the SAW device 3e does not include the functional layer 14 that is included in the SAW device 3d. In such embodiments that do not include the functional layer 14, using quartz or like material for the support substrate 10 may be preferred.

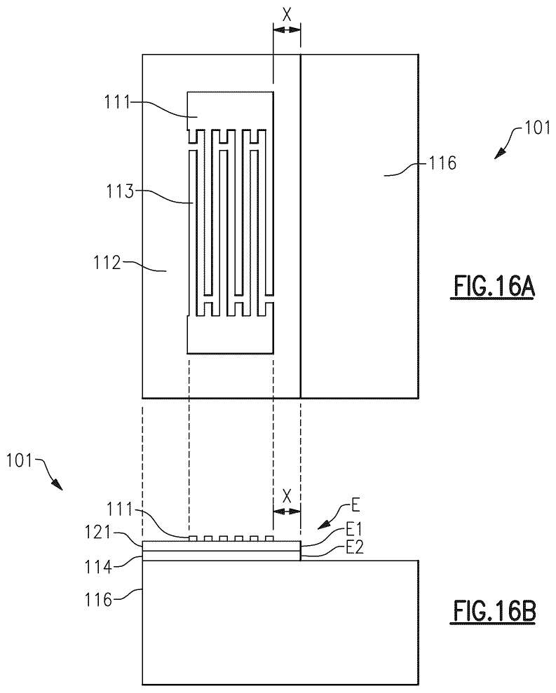

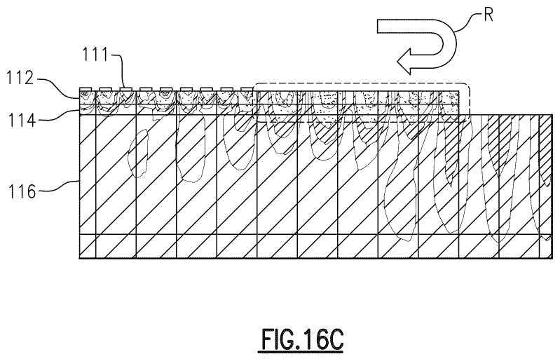

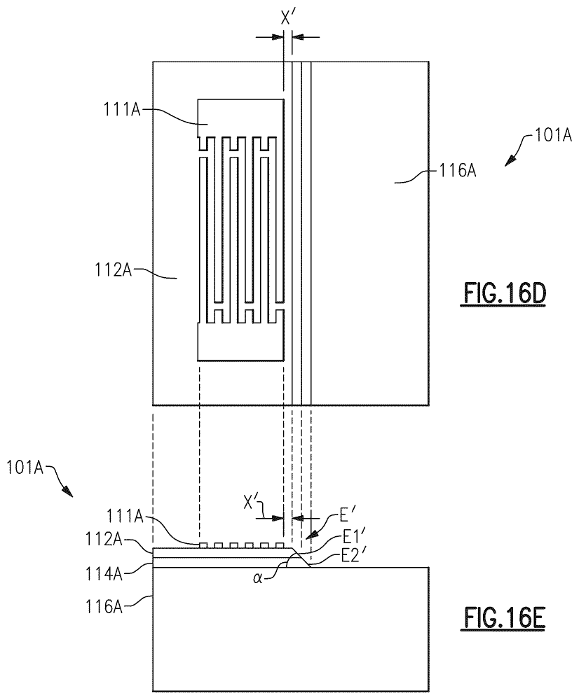

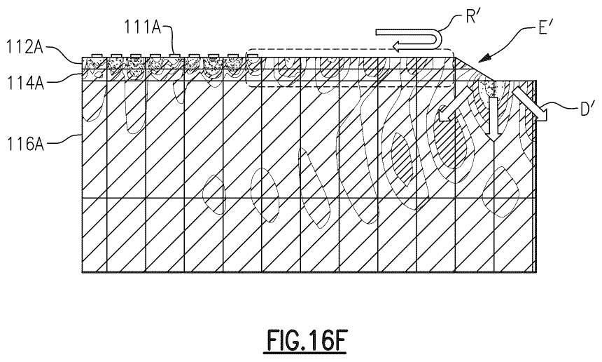

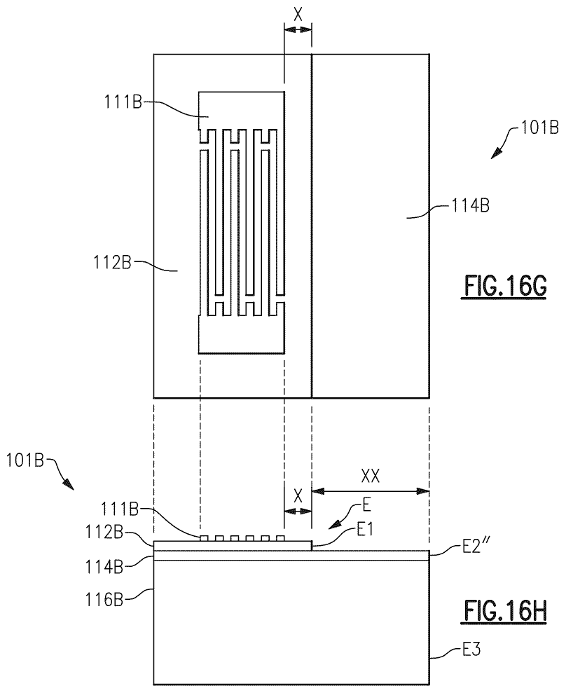

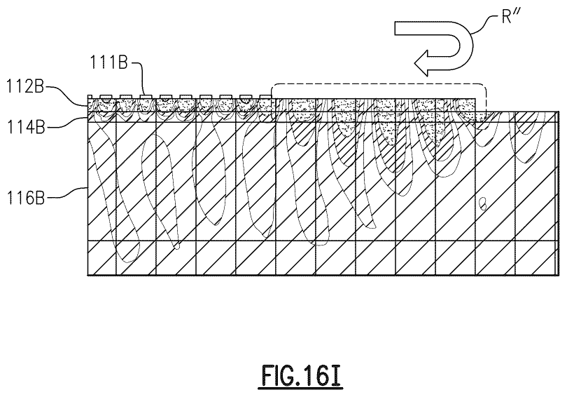

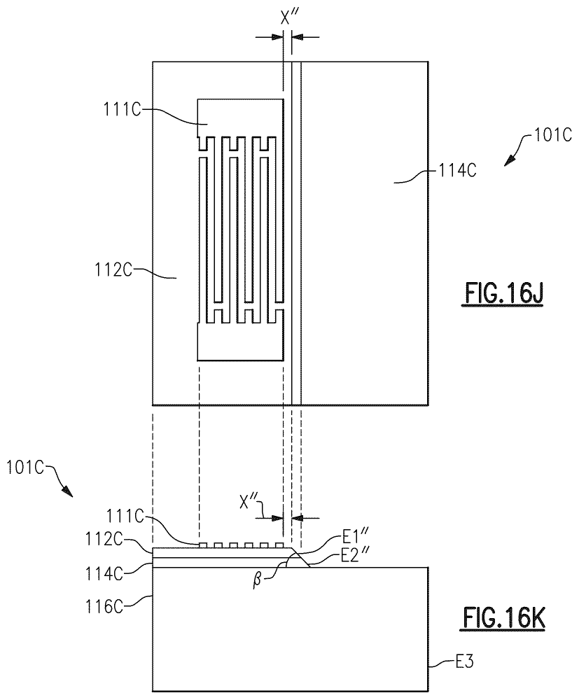

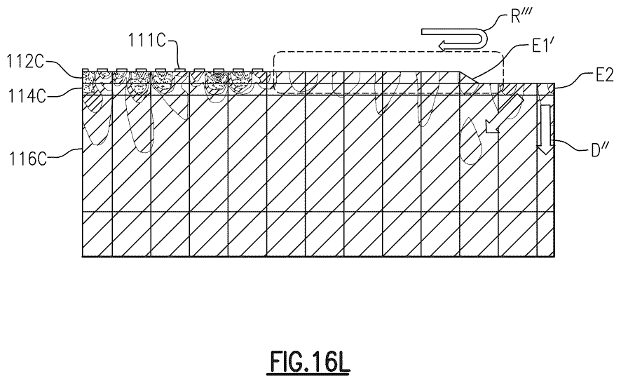

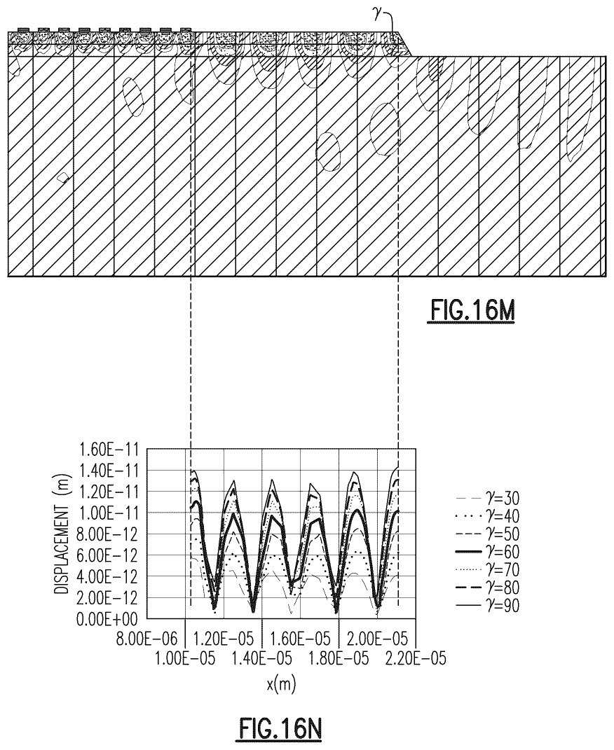

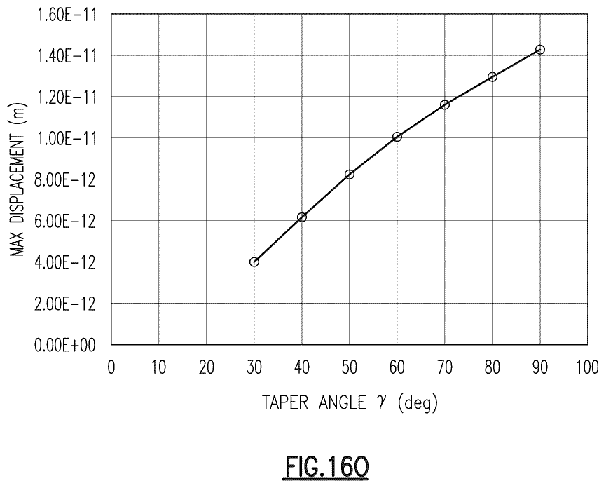

The sloped region 28, the edge region 30, the sloped region 32, the removed portion 50, and the sloped region 74 disclosed herein can prevent or reduce unwanted reflections in a SAW device. FIGS. 16A to 160 describe structures and functions of a tapered edge. The structures and functions of the tapered edge described in FIGS. 16A to 160 can be applied or implemented in the sloped region 28, the edge region 30, the sloped region 32, the removed portion 50, and the sloped region 74.

FIGS. 16A and 16B show a schematic top view and a schematic cross-sectional side view of an end portion of a SAW device 101. An interdigital transducer (IDT) electrode 111 having a plurality of fingers 113 is disposed on a piezoelectric layer 112. An outer edge E includes an outer edge E1 of the piezoelectric layer 112 and an outer edge E2 of a functional (e.g., dielectric, temperature compensation) layer 114. The IDT electrode 111 is spaced from the outer edge E1 of the piezoelectric layer 112 by a distance X. The outer edge E1 of the piezoelectric layer 112 is aligned with the outer edge E2 of the functional layer 114. The outer edge E (e.g., outer edge E1 of the piezoelectric layer and outer edge E2 of the functional layer 114) can be perpendicular to a surface of a substrate 116 (e.g., vertical orientation when the substrate 116 extends horizontally).

FIG. 16C shows an image of acoustic wave propagation in the SAW device 101. FIG. 16C shows that having the outer edge E (e.g., outer edge E1 of the piezoelectric layer 112 and outer edge E2 of the functional layer 114) perpendicular to a surface of the substrate 116 results in a large (e.g., strong) edge acoustic reflection R, which may affect (e.g., worsen) the performance of the SAW device 101.

Altering the shape of the outer edge E1 of the piezoelectric layer 112 and/or the outer edge E2 of the functional layer E2 can reduce the edge acoustic reflection (e.g., acoustic reflection magnitude) for a packaged acoustic wave component, such as the SAW device 101. FIGS. 16D and 16E show a schematic top view and a schematic cross-sectional side view of an end portion of a SAW device 101A. The SAW device 101A is similar to the SAW device 101 of FIGS. 16A-16C. Reference numerals used to designate the various components of the SAW device 101A are identical to those used for identifying the corresponding components of the SAW device 101, except that an “A” has been added to the numerical identifier. The structure and description for the various features and components of the SAW device 101 can apply to the corresponding features of the SAW device 101A, except as described below.

The SAW device 101A differs from the SAW device 101 in that the outer edge E′ (e.g., outer edge E1′ of the piezoelectric layer 112A and outer edge E2′ of the functional layer 114A) is tapered at an angle a (e.g., at a non-perpendicular angle, such as an acute angle) relative to the substrate 116A. The IDT 111A is spaced from the outer edge E1′ of the piezoelectric layer 112A by a distance X′. The outer edge E1′ of the piezoelectric layer 112A and the outer edge E2′ of the functional layer 114A can be aligned so that they extend along the same plane along the angle a, and so that the functional layer 114A extends further outward than the piezoelectric layer 112A.

FIG. 16F shows a simulation of an image of acoustic wave propagation in the SAW device 101A. FIG. 16F shows that having the outer edge E′ (e.g., outer edge E1′ of the piezoelectric layer 112A and outer edge E2′ of the functional layer 114A) tapered relative to (a surface of) the substrate 116 results in a reduced edge acoustic reflection R′ as compared to the SAW device 101, and more of the acoustic wave is deflected D′, which improves the performance of the SAW device 101A.

FIGS. 16G and 16H show a schematic top view and a schematic cross-sectional side view of an end portion of a SAW device 101B. The SAW device 101B is similar to the SAW device 101. Reference numerals used to designate the various components of the SAW device 101B are identical to those used for identifying the corresponding components of the SAW device 101, except that a “B” has been added to the numerical identifier. The structure and description for the various features and components of the SAW device 201 in can apply to the corresponding features of the SAW device 101B, except as described below.

The SAW device 101B differs from the 101 in that the outer edge E2″ of the functional layer 114B extends to and is aligned with an outer edge E3 of the substrate 116B and spaced from the outer edge E1 of the piezoelectric layer 112B by a distance XX. The outer edge E1 of the piezoelectric layer 112B is perpendicular to (a surface of) the functional layer 114B. The outer edge E2″ of the functional layer 114B is aligned (e.g., co-planar) with the outer edge E3 of the substrate 116B.

FIG. 16I shows an image of acoustic wave propagation in the SAW device 101B. FIG. 16I shows that having the outer edge E2″ of the functional layer 114B aligned with an outer edge E3 of the substrate 116B and spaced from the outer edge E1 of the piezoelectric layer 112B by a distance XX results in an increased (e.g., strong) edge acoustic reflection R″, which can affect (e.g., worsen) the performance of the SAW device 101A in a filter.

FIGS. 16J and 16K show a schematic top view and a schematic cross-sectional side view of an end portion of a SAW device 101C. The SAW device 101C is similar to the SAW device 101B. Reference numerals used to designate the various components of the SAW device 101C are identical to those used for identifying the corresponding components of the SAW device 101B, except that a “C” instead of a “B” has been added to the numerical identifier. The structure and description for the various features and components of the SAW device 101B can apply to the corresponding features of the SAW device 101C, except as described below.

The SAW device 101C differs from the SAW device 101B in that the outer edge E1′ of the piezoelectric layer 112C is tapered at an angle β (e.g., at a non-perpendicular angle, such as an acute angle) relative to the functional layer 114C. The IDT 111C is spaced from the tapered outer edge E1′ of the piezoelectric layer 112C by a distance X″.

FIG. 16L shows an image of acoustic wave propagation in the SAW device 101C. FIG. 16L shows that having the outer edge E1′ of the piezoelectric layer 112C is tapered at an angle β (e.g., at a non-perpendicular angle, such as an acute angle) relative to the functional layer 114C results in a reduced edge acoustic reflection R″′ as compared to the SAW device 101B, and more of the acoustic wave is deflected D″, which improves the performance of the SAW device 101C.

FIG. 16M shows an image of acoustic wave propagation in the SAW device 101A. FIG. 16N shows a graph of displacement or spatial vibration magnitude (which provide an indication of acoustic reflection) for the acoustic wave in the SAW device of FIG. 16M versus location along the SAW device 101A for various values of taper angle γ of the piezoelectric layer (and functional layer) relative to the substrate of the MPS. FIG. 16O shows a graph of maximum displacement or maximum spatial vibration magnitude in FIG. 16N for the acoustic wave in the SAW device 101A versus tape angle γ for the edge of the piezoelectric layer (and functional layer) relative to the substrate of the SAW device 101A. As shown in FIG. 16O, a taper angle γ of 60 degrees for the outer edge of the piezoelectric layer (and functional layer) results in a reduction in the maximum displacement or maximum spatial vibration magnitude for the acoustic wave in the SAW device 101A of approximately 29% as compared to the SAW device 101A having an outer edge for the piezoelectric layer (and functional layer) that is perpendicular (e.g., at angle γ of 90 degrees) relative to the substrate (e.g., (1.40E−11−1.00E−11)/1.40E−11). Similarly, a taper angle γ of 80 degrees results in a reduction in the maximum displacement or maximum spatial vibration magnitude for the acoustic wave in the SAW device 101A of approximately 14%. Therefore, having a taper angle γ of less than 90 degrees (e.g., between 30 degrees and 89 degrees) for the outer edge of the piezoelectric layer (and functional layer) results in a reduction in acoustic reflection for the SAW device 101A, as compared to the SAW device 101A having an outer edge for the piezoelectric layer (and functional layer) that is perpendicular (e.g., at angle γ of 90 degrees) relative to the substrate. In some implementations, the taper angle γ outer edge for the piezoelectric layer (and functional layer) relative to the substrate layer can preferably be between 45 degrees and 80 degrees (e.g., 45 degrees, 50 degrees, 60 degrees, 80 degrees, and values in between).

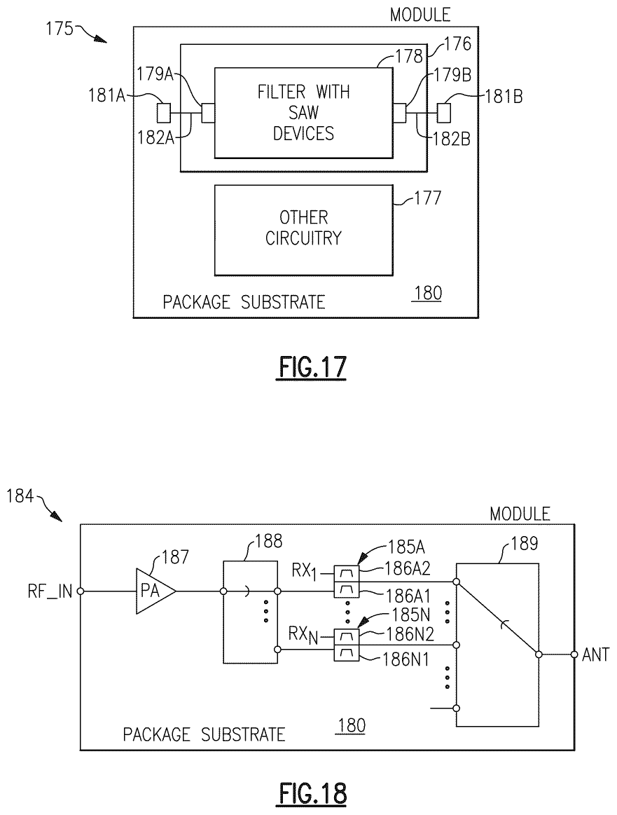

FIG. 17 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW devices with any suitable combination of features of the SAW devices disclosed herein. The SAW component 176 can include a SAW die that includes one or more MMS filters and/or one or more SAW resonators.

The SAW component 176 shown in FIG. 17 includes a filter 178 and terminals 179A and 179B. The filter 178 includes SAW devices. One or more of the SAW devices can be implemented in accordance with any suitable principles and advantages disclosed herein. The terminals 179A and 178B can serve, for example, as an input contact and an output contact. The SAW component 176 and the other circuitry 177 are on a common packaging substrate 180 in FIG. 17. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

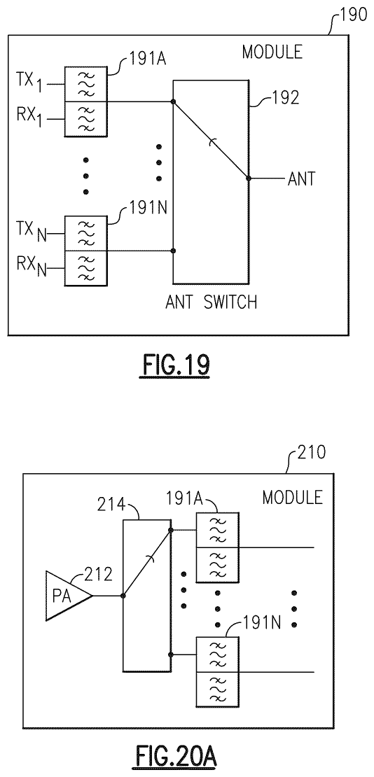

FIG. 18 is a schematic diagram of a radio frequency module 184 that includes a surface acoustic wave device according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW devices in accordance with any suitable principles and advantages disclosed herein. Similarly, one or more of the receive filters 186A2 to 186N2 can include one or more SAW devices in accordance with any suitable principles and advantages disclosed herein. Although FIG. 18 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 19 is a schematic block diagram of a module 190 that includes duplexers 191A to 191N and an antenna switch 192. One or more filters of the duplexers 191A to 191N can include any suitable number of surface acoustic wave devices in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190. MMS filters disclosed herein can be implemented in receive filters of one or more of the duplexers 191A to 191N, for example.

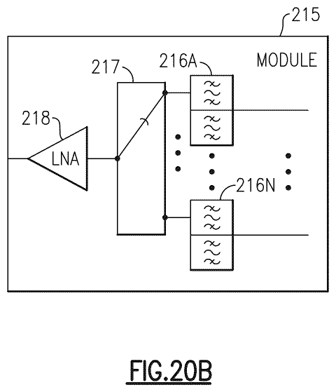

FIG. 20A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave devices in accordance with any suitable principles and advantages discussed herein. Any suitable number of duplexers 191A to 191N can be implemented.

FIG. 20B is a schematic block diagram of a module 215 that includes filters 216A to 216N, a radio frequency switch 217, and a low noise amplifier 218 according to an embodiment. One or more filters of the filters 216A to 216N can include any suitable number of MMS filters and/or acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

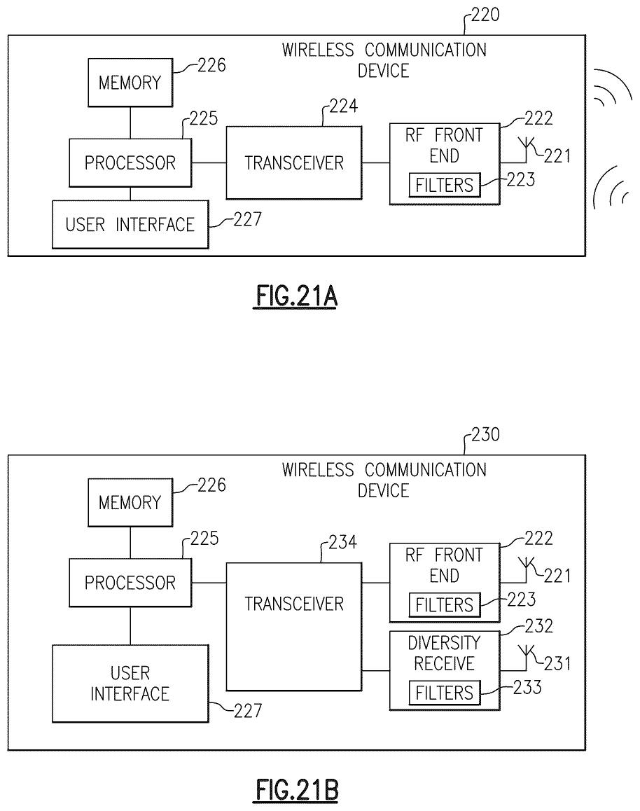

FIG. 21A is a schematic diagram of a wireless communication device 220 that includes filters 223 in a radio frequency front end 222 according to an embodiment. The filters 223 can include one or more SAW devices in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW devices of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 21B is a schematic diagram of a wireless communication device 230 that includes filters 223 in a radio frequency front end 222 and a second filter 233 in a diversity receive module 232. The wireless communication device 230 is like the wireless communication device 200 of FIG. 21A, except that the wireless communication device 230 also includes diversity receive features. As illustrated in FIG. 21B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW devices that include any suitable combination of features discussed with reference to any embodiments discussed above. The diversity module 232 and the radio frequency front end 222 can together be considered part of a radio frequency front end.

Although embodiments disclosed herein relate to surface acoustic wave filters and/or resonators, any suitable principles and advantages disclosed herein can be applied to other types of acoustic wave devices that include an IDT electrode, such as Lamb wave devices and/or boundary wave devices. For example, any suitable combination of features of the acoustic velocity adjustment structures disclosed herein can be applied to a Lamb wave device and/or a boundary wave device.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a support substrate structure;
a first piezoelectric layer over the support substrate structure;
a second piezoelectric layer over the first piezoelectric layer, the second piezoelectric layer having a first region having a first thickness and a second region having a second thickness different from the first thickness;
a first acoustic wave element positioned in the first region; and
a second acoustic wave element positioned in the second region.

2. The surface acoustic wave device of claim 1 wherein the support substrate structure includes a support substrate, the support substrate is a silicon layer, a quartz layer, a ceramic layer, a glass layer, a spinel layer, a magnesium oxide spinel layer, a sapphire layer, a diamond layer, a silicon carbide layer, a silicon nitride layer, or an aluminum nitride layer.

3. The surface acoustic wave device of claim 2 wherein the support substrate structure also includes a functional layer and a trap rich layer between the support substrate and the functional layer, the functional layer is a silicon dioxide layer.

4. The surface acoustic wave device of claim 1 wherein the first piezoelectric layer is a lithium tantalate layer.

5. The surface acoustic wave device of claim 4 wherein the second piezoelectric layer is a lithium niobate layer.

6. The surface acoustic wave device of claim 1 wherein a thickness of the second piezoelectric layer is less than 500 nm.

7. The surface acoustic wave device of claim 1 wherein a thickness of the second piezoelectric layer is less than 250 nm.

8. The surface acoustic wave device of claim 1 wherein the first and second acoustic wave elements are formed on or at least partially in the second piezoelectric layer.

9. The surface acoustic wave device of claim 1 wherein the first acoustic wave element is an interdigital transducer electrode.

10. The surface acoustic wave device of claim 1 wherein the first acoustic wave element is a first filter and the second acoustic wave element is a second filter.

11. The surface acoustic wave device of claim 1 wherein the first acoustic wave element is a series resonator and the second acoustic wave element is a shunt resonator.

12. A surface acoustic wave device comprising:
a support substrate structure;
a piezoelectric structure including a first piezoelectric layer and a second piezoelectric layer over the support substrate structure, a first region of the piezoelectric structure having a first combination of thicknesses of the first and second piezoelectric layers and a second region having a second combination of thicknesses of the first and second piezoelectric layers different from the first combination;
a first surface acoustic wave element positioned in the first region; and
a second surface acoustic wave element positioned in the second region.

13. The surface acoustic wave device of claim 12 wherein the first piezoelectric layer is a lithium tantalate layer.

14. The surface acoustic wave device of claim 13 wherein the second piezoelectric layer is a lithium niobate layer.

15. The surface acoustic wave device of claim 12 wherein the first acoustic wave element is a first filter and the second acoustic wave element is a second filter.

16. The surface acoustic wave device of claim 12 wherein the first acoustic wave element is a series resonator and the second acoustic wave element is a shunt resonator.

17. A surface acoustic wave device comprising:
a multilayer piezoelectric substrate including a support substrate, a first piezoelectric layer, and a second piezoelectric layer;
a first surface acoustic wave element in electrical communication with the multilayer piezoelectric substrate and positioned in a first region of the multilayer piezoelectric substrate having a first combination of thicknesses of the first and second piezoelectric layers; and
a second surface acoustic wave element in electrical communication with multilayer piezoelectric substrate and positioned in a second region of the multilayer piezoelectric substrate having a second combination of thicknesses of the first and second piezoelectric layers different from the first combination.

18. The surface acoustic wave device of claim 17 wherein the first piezoelectric layer is a lithium tantalate layer.

19. The surface acoustic wave device of claim 18 wherein the second piezoelectric layer is a lithium niobate layer.

20. The surface acoustic wave device of claim 17 wherein the first acoustic wave element is a series resonator and the second acoustic wave element is a shunt resonator.
